(19) United States
(12) Patent Application Publication
(10) Pub. No.: US 2021/0212243 A1
(43) Pub. Date: Jul. 8, 2021

(54) ELECTROMAGNETIC SHIELDING FILM AND METHOD FOR MAKING SAME

(71) Applicant: GUANGDONG UNIVERSITY OF PETROCHEMICAL TECHNOLOGY, Maoming (CN)

(72) Inventors: Dang WU, Maoming (CN); Xiaolin YANG, Maoming (CN); Minghui JING, Maoming (CN); Shuming YUAN, Maoming (CN)

(21) Appl. No.: 17/056,674

(22) PCT Filed: Apr. 29, 2020
(86) PCT No.: PCT/CN2020/087708

§ 371 Date: Nov. 18, 2020

(30) Foreign Application Priority Data
May 8, 2019 (CN) 201910381778.4

(51) Int. Cl. H05K 9/00; C01B 32/174; C01G 53/00; C01G 51/00; C01G 5/00; C01G 3/00; C01G 49/08

(52) U.S. Cl. CPC H05K 9/0075; H05K 9/0088; H05K 9/009; H05K 9/0094; C01B 32/174; B82Y 25/00; C01G 51/00; C01G 5/00; C01G 3/00; C01G 49/08; C01G 53/00

(57) ABSTRACT

An electromagnetic shielding film and a method for making the same. The method includes: dispersing a conductive agent and a magnetic nanomaterial in sodium alginate solutions to form an electrically conductive shielding solution and a magnetic field shielding solution, respectively; applying the electrically conductive and magnetic field shielding solutions onto two opposite surfaces of a transparent substrate to form an electrically conductive shielding layer and a magnetic field shielding layer, respectively, so that an electromagnetic shielding film precursor of a sandwich structure is obtained; and placing the film precursor in a calcium chloride solution to perform a crosslinking process to cure the layers, so as to obtain an electromagnetic shielding film product after being rinsed and dried. The electric and magnetic fields shielding layers of the film can each have a uniform thickness and cooperate to provide an improved shielding effect and superior performances for the film.

### CROSS-REFERENCE TO RELATED APPLICATIONS

The present application is a U.S. national stage application for International Application No. PCT/CN2020/087708, filed Apr. 29, 2020 and the entire contents of which are incorporated herein by reference, which claims priority to Chinese Application No. 201910381778.4, filed May 8, 2019 and the entire contents of which are incorporated herein by reference.

### TECHNICAL FIELD

The present disclosure is related to the field of electromagnetic shielding coatings, and in particular to an electromagnetic shielding film and a method for making the same.

### Background

As society becomes increasingly information dependent, the widespread use of electric power in production and life and the development of electronic and communication technologies cause electromagnetic fields or waves to be present in the living environment of human beings. Electromagnetic interference (EMI) occurs in the frequency range of 10 KHz to 10 GHz, and mainly includes carrier frequency interference (10 to 300 KHz), radio frequency interference, video interference (300 KHz to 300 MHz), and partial microwave interference (30 MHz to 300 GHz). EMI could mainly affect normal operations of various electronic devices, causing leakage of electromagnetic information and adverse influence on organisms including human beings.

EMI or electromagnetic shields are mainly intended for use at high frequencies. Such shields are required to provide good electrical continuity and can cancel the electromagnetic waves from the outside by means of eddy currents generated in the conductive materials of the shields, achieving a shielding effect of the shields. The shielding effect, provided by an electromagnetic shielding material is closely related to relative conductivity and permeability of, and thickness of the material, as well as to frequencies of incident electromagnetic waves. The shields need to be made of different materials so as to shield different types of interferences. Current, there are two types of commonly used shielding materials, that are: a highly electrically conductive material (i.e., with high electrical conductivity), which is typically used for applications requiring electric and/or magnetic fields shielding and the shielding effect of which is mainly determined by losses due to multiple reflections occurred inside the material instead of by absorption losses; and a material with high magnetic permeability, which is typically used for applications requiring magnetic field shielding and in which magnetic field attenuation is mainly determined by absorption losses instead of reflection losses occurred inside the material. In order to make a shield have a good shielding effect for electromagnetic waves with frequencies in a wide range, the reflection losses should be as high as possible. For this purpose, it is desirable that the electromagnetic shielding material has a higher electrical conductivity and some thickness.

Electromagnetic shielding films currently available on the market are generally complex in structure and simple in function. The existing coatable electromagnetic shielding materials usually contain an oxidizable metallic component, have poor adhesion to substrates, and tend, for example, to crack or flake. Moreover, these materials have poor mechanical properties and a simple function.

Silver nanomaterials exhibit a high optical transparency, a low haze, a high electrical conductivity and a high toughness because of their excellent catalytic, optical, and electrical properties. Silver nanowires with excellent flexibility have become a research hotspot in recent years. Transparent conductive films are electrically conductive and have a high transparency in the visible light wavelength region. So, for such transparent conductive films, both of these two properties are desired. However, the conductivity of the transparent conductive films has a negative correlation with the transparency thereof, that is, as the thickness of the films increases, the conductivity thereof increases, but the transparency decreases.

Further, in the case of alternating electromagnetic fields, there exists both the electric fields and the magnetic fields in the same space. In this case, it is desirable to shield both of these two fields. As frequencies change, EMI Effects of the alternating electromagnetic fields may change and should be differentiated in an actual situation.

Therefore, it is of important research significance and application value to research and develop an electromagnetic shielding film having a good optical transparency, a low haze, and a high electrical conductivity and capable of shielding both the electric fields and the magnetic fields.

### SUMMARY

To overcome the above problems in the prior art, i.e., the existing electromagnetic shielding films cannot afford an balance of their transparency, haze, and electrical conductivity and are intended mainly for shielding the magnetic fields, an objective of the present disclosure is to provide a method for making an electromagnetic shielding film. The method of the present disclosure proposes to form, on opposite surfaces of a transparent substrate, an electrically conductive shielding layer and a magnetic field shielding layer, respectively, by coating techniques, each layer having a controlled thickness, and conductive agent particles and magnetic nanoparticles being uniformly distributed in the electrically conductive shielding layer and the magnetic field shielding layer, respectively. The method can make an electromagnetic shielding film with a high transparency and conductivity, and a low haze. Also, the method is inexpensive to implement. The electrically conductive shielding layer and the magnetic field shielding layer of the film cooperate to provide a substantially improved electromagnetic shielding effectiveness for the film. Further, according to the method of the present disclosure, an aqueous sodium alginate solution, containing a conductive agent or magnetic nanoparticles, and a calcium chloride solution are employed to perform a gelation reaction therebetween, so as to crosslink the sodium alginate, causing reduction in volume and inner stress to be applied to the conductive agent particles and the magnetic nanoparticles in the layers. In this way, interactions between the conductive agent particles and between the magnetic nanoparticles can be enhanced, and the conductivity and bulk density can be increased. Finally, the electromagnetic shielding effectiveness and adhesive properties of the layers can be improved again.

The electric and magnetic fields shielding layers of the electromagnetic fielding film, made by the present method, can each have a uniform thickness, and they cooperate to provide an improved shielding effect and superior performances for the film. Moreover, each of these two functional layers has a good adhesive property and is resistant to cracking, flaking, and oxidizing. In view of the manufacturing process and structural performances of the present film, the solution of the present disclosure complies with the future development trends of the electromagnetic shielding materials and thus gives very broad development prospects.

A further objective of the present disclosure is to provide an electromagnetic shielding film.

An objective of the present disclosure is realized by a method for making an electromagnetic shielding film, comprising steps of:

S1: dispersing a conductive agent and a magnetic nanomaterial in sodium alginate solutions to form an electrically conductive shielding solution and a magnetic field shielding solution, respectively;

S2: applying the electrically conductive and magnetic field shielding solutions onto two opposite surfaces of a transparent substrate to form an electrically conductive shielding layer and a magnetic field shielding layer, respectively, so that an electromagnetic shielding film precursor with a sandwiched structure is obtained; and

S3: placing the film precursor obtained in the step S2 in a calcium chloride solution to perform a crosslinking process to cure the layers, so as to obtain an electromagnetic shielding film product after being rinsed and dried.

Typical methods for making an electromagnetic shielding film include electroless plating, vacuum coating, metal spraying, and metal foil applying. In the case of applying electrically conductive coatings, most resin components contained therein usually require heat to cure, and some require addition of a curing agent, causing the metallic power in the coatings to subject to oxidation or other reactions and resulting in adverse affect on the conductivity and shielding effect of the conductive coatings. Moreover, during the high temperature cure, the coatings tend, for example, to crack or flake. In the case of applying metal foils, it is difficult for the metal foils to be applied onto a complex profile. The metal spraying method may produce metal coatings having poor adhesion to substrates and cause harm to human health. Electromagnetic shielding film performance requirements are driven higher, and the main challenge in production of such electromagnetic shielding films is how to achieve a controlled thickness of a functional layer of the films and a uniform distribution of nanoparticles in a functional layer of the films. The known vacuum technologies for making such films, for example, magnetron sputtering, are cost-intensive, and their development is restricted by limited material diversity. Moreover, the printing methods for making electromagnetic shielding films have problems such as agglomeration, generation of air bubbles, and a difficulty in the realization of low-cost production of a functional layer, having a nanoscale thickness, of the films.

In view of the problems described above, the present disclosure provides a new method for making an electromagnetic shielding film According to the method, firstly a conductive agent and a magnetic nanomaterial are respectively mixed into an aqueous sodium alginate solution to form respective mixed solutions. Since the aqueous sodium alginate solution has a certain level of viscosity, uniform distribution of the conductive agent particles and the magnetic nanomaterial in the respective mixed solutions is facilitated. According to the method, an electrically conductive shielding layer and a magnetic field shielding layer are then formed on opposite surfaces of a transparent substrate by applying thereon the mixed solution containing the conductive agent and the mixed solution containing the magnetic nanomaterial, respectively. The thicknesses of the two layers are controllable, and the conductive agent particles and the magnetic nanomaterial are uniformly distributed in the respective layers. In this way, it is possible to obtain an electromagnetic shielding film having a high transparency and conductivity and a low haze, in a low cost manner. The electrically conductive shielding layer and the magnetic field shielding layer cooperate to provide a substantially improved electromagnetic shielding effect. Moreover, forming the functional layers on opposite surfaces of a transparent substrate makes it possible to perform the subsequent crosslinking process only once, so as to form the film product in a simple and quick manner. Thus, the production efficiency is improved.

Further, since sodium alginate can be crosslinked by a calcium chloride solution, optionally at room temperature, causing gelling of the sodium alginate solution and then reduction in volume. This may in turn cause inner stress to be applied to the conductive agent particles and the magnetic nanoparticles in the functional layers. In this way, interactions between the conductive agent particles and between the magnetic nanoparticles can be enhanced, and the conductivity and bulk density can be increased. Therefore, the electromagnetic shielding effectiveness and adhesive properties of the layers can be improved again. Since sodium alginate is bio-friendly and environmentally friendly, enabling the resulting electromagnetic shielding film to have a wide range of applications.

The electric and magnetic fields shielding layers of the film, made by the present method, each have a uniform thickness, and they cooperate to provide an improved shielding effect and superior performances for the film. Each of these two functional layers has a good adhesive property and is resistant to cracking, flaking, and oxidizing. The solution of the present disclosure complies with the future development trends of the electromagnetic shielding materials and thus gives very broad development prospects.

Preferably, in the step S1, the mass ratio of the sodium alginate to the conductive agent in the electrically conductive shielding solution is in the range of 3 to 100, further preferably 3 to 50.

The conductivity of the conductive agent and its proportion in the mixed solution directly influence the electromagnetic shielding performance of the formed layer. In the case that the electrically conductive shielding layer contains a one-dimensional nano-structured material, its percolation threshold can be reached at a lower concentration of the material. Since the main loss mechanism in the electrically conductive shielding layer comes from the resistance thereof, the electromagnetic shielding effectiveness of the layer is related to the conductivity of the conductive material in particular, the higher the conductivity, the greater the macro currents caused by current carriers, and it is advantageous in converting the electromagnetic energy to the thermal energy. The electromagnetic shielding effectiveness of the resulting film product can thus be improved.

Preferably, in the step S1, the conductive agent may be one or more of carbon nanotubes, graphene, silver nanowires, copper nanowires, polythiophene, and polypyrrole.

Further preferably, the conductive agent may be one or more of carbon nanotubes, silver nanowires, and copper nanowires.

Preferably, in the step S1, the mass ratio of the sodium alginate to the magnetic nanomaterial in the magnetic field shielding solution is in the range of 1 to 50.

According to the method of the disclosure, any conventional magnetic nanomaterial may be used.

Preferably, the magnetic nanomaterial used in the step S1 may be one or more of nickel, cobalt, and ferrosoferric oxide.

The magnetic nanomaterial described above can provide electromagnetic shielding via magnetic loss.

Preferably, in the step S1, the magnetic nanomaterial used in the step S1 may be one or more of nanowires, nanochains, nanoparticles, nanorods and nanosheets, formed of metal or metal alloy.

The metal or metal alloy nanowire may be nickel, cobalt, ferrosoferric oxide, or magnetic alloy nanowires, for example. The magnetic alloy may be formed of at least two of nickel, cobalt, and ferrosoferric oxide.

According to the method of the disclosure, the transparent substrate in the step S2 may be formed of any conventional suitable material.

Preferably, such suitable material may be polyethylene terephthalate (PET), polymethylmethacrylate (PMMA), polycarbonate (PC), polyethylene (PE), polystyrene (PS), polyimide (PI) or polyvinyl alcohol (PVA).

Preferably, the step S2 may further comprise, before applying the electrically conductive and magnetic field shielding solutions onto opposite surfaces of a transparent substrate, rinsing the opposite surfaces of the substrate.

The thicknesses of the substrate, and of the electrically conductive and magnetic field shielding layers may be varied as desired.

Preferably, the substrate used in the step S2 may have a thickness of 10 to 500 μm.

Preferably, the electrically conductive shielding layer formed in the step S2 may have a thickness of 0.02 to 1 mm.

Preferably, the magnetic field shielding layer formed in the step S2 may have a thickness of 0.02 to 1 mm.

Preferably, the calcium chloride solution used in the step S3 may have a CaCl₂ concentration of 1 to 10 wt. %.

The present disclosure further provides an electromagnetic shielding film, made by the method described above.

Embodiments of the present disclosure provide several advantages over prior art.

The present electromagnetic shielding film can be used for shielding both the electric fields and the magnetic fields. The electrically conductive and magnetic field shielding layers of the film cooperate to provide a substantially improved electromagnetic shielding effectiveness for the film.

According to embodiments of the disclosure, sodium alginate is used to prepare electrically conductive and magnetic field shielding solutions. The aqueous sodium alginate solution has a certain level of viscosity, which can facilitate distribution of the conductive agent and the magnetic nanomaterial in the respective solutions. Subsequent crosslinking of the sodium alginate by a calcium chloride solution enables the electrically conductive and magnetic field shielding layers to have a strong adhesion (to opposite surfaces of the substrate) and a high transparency in a simple and quick manner. Moreover, interactions between the conductive agent particles and between the magnetic nanoparticles can be enhanced due to inner stress generated in the functional layers by the crosslinking process, and the conductivity and bulk density can be increased. Therefore, the electromagnetic shielding effectiveness of the film can be improved again.

Sodium alginate is bio-friendly and environmentally friendly. This makes it possible for the resulting electromagnetic shielding film to have a wide range of applications.

The electric and magnetic fields shielding layers of the electromagnetic shielding film, made by the method of the present disclosure, each have a uniform thickness, and they cooperate to provide an improved shielding effect and superior performances for the film. Moreover, the two functional or shielding layers have a good adhesion to the respective surfaces of the substrate and are resistant to crack and flake. Further, since the two layers have been subjected to special processing, they are also resistant to oxidizing. The solution of the present disclosure complies with the future development trends of the electromagnetic shielding materials and thus gives very broad development prospects.

### DETAILED DESCRIPTION

Embodiments of the present disclosure will now be further described below with reference to examples. It should be understood, however, that the examplary embodiments are provided to further illustrate the present disclosure and not to be taken as limiting the scope of the disclosure. Reaction conditions not indicated in the following examplary embodiments can be conventional or can be carried out following the manufacturer's recommendations. Reagents, starting materials, and the like used in the examplary embodiments without specified manufacturers can be any commercially available ones. Any changes or modifications made by those skilled in the art under the spirit and principles of the disclosure shall fall within the scope of the disclosure.

### EXAMPLE 1

An electromagnetic shielding film, composed of a transparent substrate, an electrically conductive shielding layer applied on one surface of the substrate, and a magnetic field shielding layer applied on the other surface of the substrate, was made as follows.

A polyethylene terephthalate (PET) film with a thickness of 50 μm was used as the above transparent substrate, and was rinsed with deionized water before use.

An electrically conductive shielding solution, composed of a carbon nanotube (a conductive agent), sodium alginate, and water with a mass ratio of 3:10:1000, was applied onto one surface of the PET substrate to form thereon an electrically conductive shielding layer having a thickness of 50 μm.

A magnetic field shielding solution, composed of a magnetic cobalt nanowire, sodium alginate, and water with a mass ratio of 20:60:1000, was applied onto the other surface of the PET substrate without the electrically conductive shielding layer, to form thereon a magnetic field shielding layer having a thickness of 50 μm.

The resulting film precursor of the sandwich structure was then placed in a calcium chloride solution with a concentration of 5 wt. % to perform a crosslinking process. Thereafter, the film was rinsed with deionized water, and dried at 50° C. for 30 minutes to obtain an electromagnetic shielding film product.

### EXAMPLE 2

An electromagnetic shielding film, composed of a transparent substrate, an electrically conductive shielding layer applied on one surface of the substrate, and a magnetic field shielding layer applied on the other surface of the substrate, was made as follows.

A polyimide (PI) film with a thickness of 60 μm was used as the above transparent substrate, and was rinsed with deionized water before use.

An electrically conductive shielding solution, composed of a silver nanowire (a conductive agent), sodium alginate, and water with a mass ratio of 3:10:1000, was applied onto one surface of the PI substrate to form thereon an electrically conductive shielding layer having a thickness of 50 μm.

A magnetic field shielding solution, composed of a magnetic nickel nanowire, sodium alginate, and water with a mass ratio of 20:60:1000, was applied onto the other surface of the PI substrate without the electrically conductive shielding layer, to form thereon a magnetic field shielding layer having a thickness of 100 μm.

The resulting film precursor of the sandwich structure was then placed in a calcium chloride solution with a concentration of 3 wt. % to perform a crosslinking process. Thereafter, the film was rinsed with deionized water, and dried at 80° C. for 30 minutes to obtain an electromagnetic shielding film product.

### EXAMPLE 3

An electromagnetic shielding film, composed of a transparent substrate, an electrically conductive shielding layer applied on one surface of the substrate, and a magnetic field shielding layer applied on the other surface of the substrate, was made as follows.

A polyethylene (PE) film with a thickness of 30 μm was used as the above transparent substrate, and was rinsed with deionized water before use.

An electrically conductive shielding solution, composed of a copper nanowire (a conductive agent), sodium alginate, and water with a mass ratio of 6:75:1000, was applied onto one surface of the PE substrate to form thereon an electrically conductive shielding layer having a thickness of 100 μm.

A magnetic field shielding solution, composed of a magnetic ferrosoferric oxide nanowire, sodium alginate, and water with a mass ratio of 25:50:1000, was applied onto the other surface of the PE substrate without the electrically conductive shielding layer, to form thereon a magnetic field shielding layer having a thickness of 150 μm.

The resulting film precursor of the sandwich structure was then placed in a calcium chloride solution with a concentration of 3 wt. % to perform a crosslinking process. Thereafter, the film was rinsed with deionized water, and dried at 80° C. for 30 minutes to obtain an electromagnetic shielding film product.

### EXAMPLE 4

An electromagnetic shielding film, composed of a transparent substrate, an electrically conductive shielding layer applied on one surface of the substrate, and a magnetic field shielding layer applied on the other surface of the substrate, was made as follows.

A polyethylene terephthalate (PET) film with a thickness of 50 μm was used as the above transparent substrate, and was rinsed with deionized water before use.

An electrically conductive shielding solution, composed of a carbon nanotube (a conductive agent), sodium alginate, and water with a mass ratio of 6:75:1000, was applied onto one surface of the PET substrate to form thereon an electrically conductive shielding layer having a thickness of 100 μm.

A magnetic field shielding solution, composed of a magnetic cobalt nanowire, sodium alginate, and water with a mass ratio of 1:50:1000, was applied onto the other surface of the PET substrate without the electrically conductive shielding layer, to form thereon a magnetic field shielding layer having a thickness of 150 μm.

The resulting film precursor of the sandwich structure was then placed in a calcium chloride solution with a concentration of 5 wt. % to perform a crosslinking process. Thereafter, the film was rinsed with deionized water, and dried at 50° C. for 30 minutes to obtain an electromagnetic shielding film product.

### EXAMPLE 5

An electromagnetic shielding film, composed of a transparent substrate, an electrically conductive shielding layer applied on one surface of the substrate, and a magnetic field shielding layer applied on the other surface of the substrate, was made as follows.

A polyethylene terephthalate (PET) film with a thickness of 50 μm was used as the above transparent substrate, and was rinsed with deionized water before use.

An electrically conductive shielding solution, composed of a carbon nanotube (a conductive agent), sodium alginate, and water with a mass ratio of 3:10:1000, was applied onto one surface of the PET substrate to form thereon an electrically conductive shielding layer having a thickness of 100 μm.

A magnetic field shielding solution, composed of a magnetic cobalt nanowire, sodium alginate, and water with a mass ratio of 20:60:1000, was applied onto the other surface of the PET substrate without the electrically conductive shielding layer, to form thereon a magnetic field shielding layer having a thickness of 50 μm.

The resulting film precursor of the sandwich structure was then placed in a calcium chloride solution with a concentration of 5 wt. % to perform a crosslinking process. Thereafter, the film was rinsed with deionized water, and dried at 50° C. for 30 minutes to obtain an electromagnetic shielding film product.

### COMPARATIVE EXAMPLE 1

An electromagnetic shielding film was made in the same manner as in Example 1 expect that the electrically conductive shielding solution and the magnetic field shielding solution contained no sodium alginate, and that the film precursor resulting from applying the solutions onto respective surfaces of the substrate was not subjected to the crosslinking process in the calcium chloride solution and also not subjected to the drying.

The electromagnetic shielding films made in Examples 1 to 5 and in Comparative Example 1 were tested for tensile property and surface resistance. Additionally, their electromagnetic shielding performance was measured in decibels over a range of GHz frequencies following the method of standard test GB/T12190-2006. The results of these tests are shown in Table 1 below.

TABLE 1
Test Results

| | | | Magnetic | | |
|---|---|---|---|---|---|
| | | | shielding | | |
| | | | factor after | | |
| | Surface | Magnetic | the film samples | | |
| | resistivity | shielding | being bent for | Trans- | |
| | (mΩ/sq) | factor (dB) | 1000 times (dB) | parency | Haze |
| Ex. 1 | 220 | 35 | 33 | 90 | 3.5 |
| Ex. 2 | 208 | 40 | 40 | 88 | 3.8 |
| Ex. 3 | 145 | 43 | 41 | 89 | 4.3 |
| Ex. 4 | 143 | 37 | 36 | 89 | 4.0 |
| Ex. 5 | 148 | 38 | 37 | 91 | 3.6 |
| Comp | 235 | 35 | 12 | 92 | 3.1 |
| Ex. 1 | | | | | |

From the results of Table 1, it can be seen that Examples 1-5 of the present disclosure had good shielding performance for both electric fields and magnetic fields. Also, the examples had strong adhesion, high transparency and conductivity, and low haze. The conductivity, transparency, and haze of the electromagnetic shielding film of the present disclosure can be changed depending on the intended use of the film by varying the conditions for making the same. In particular, the electric field shielding layer of Example 1 had a different thickness from that of Example 5, and the magnetic field shielding layer of Example 1 had a different thickness from that of Example 2; the results of the three examples showed that as the thickness of the electric or magnetic field shielding layer increased, the electromagnetic shielding effect and the haze were increased, and the transparency was lowered. Comparison between Example 3 and Example 4 indicates that an increase in amount of the magnetic nanomaterial in the magnetic field shielding layer can improve the electromagnetic shielding effect of the film. Moreover, comparison between Example 1 and Comparative Example 1 indicates that addition of sodium alginate can prevent flaking off of the electric and magnetic fields shielding layers from the substrate surfaces during bending of the film samples, even after many repetitions of flexion.

Therefore, the electric and magnetic fields shielding layers of the electromagnetic fielding film, made by the present method, can have a uniform thickness, and they cooperate to provide an improved shielding effect and superior performances for the film. Each of these two functional layers has a good adhesive property and is resistant to cracking, flaking, and oxidizing. The solution of the present disclosure complies with the future development trends of the electromagnetic shielding materials and thus gives very broad development prospects.

Finally, it is noted that the above examplary embodiments are provided merely for purposes of illustration and are not intended to limit the scope of the disclosure. Various substitutions or variations providing the same performances or functions, made by those skilled in the art without departing from the concept of the present disclosure, fall within the protection scope of the present disclosure.

1. A method for making an electromagnetic shielding film, comprising steps of:
S1: dispersing a conductive agent and a magnetic nanomaterial in sodium alginate solutions to form an electrically conductive shielding solution and a magnetic field shielding solution, respectively;
S2: applying the electrically conductive and magnetic field shielding solutions onto two opposite surfaces of a transparent substrate to form an electrically conductive shielding layer and a magnetic field shielding layer, respectively, so that an electromagnetic shielding film precursor of a sandwich structure is obtained; and
S3: placing the film precursor obtained in the step S2 in a calcium chloride solution to perform a crosslinking process to cure the layers, so as to obtain an electromagnetic shielding film product after being rinsed and dried.

2. The method according to claim 1, wherein, in the step S1, the mass ratio of the sodium alginate to the conductive agent in the electrically conductive shielding solution is in the range of 3 to 100.

3. The method according to claim 1 or claim 2, wherein, the conductive agent is one or more of carbon nanotubes, graphene, silver nanowires, copper nanowires, polythiophene, and polypyrrole.

4. The method according to claim 3, wherein, the conductive agent has a one-dimensional nano-structure.

5. The method according to claim 4, wherein, the conductive agent is one or more of carbon nanotubes, silver nanowires, and copper nanowires.

6. The method according to claim 1, wherein, in the step S1, the mass ratio of the sodium alginate to the magnetic nanomaterial in the magnetic field shielding solution is in the range of 1 to 50.

7. The method according to claim 1, wherein, the magnetic nanomaterial used in the step S1 is one or more of nickel, cobalt, and ferrosoferric oxide.

8. The method according to claim 1, wherein, the magnetic nanomaterial used in the step S1 is one or more of nanowires, nanochains, nanoparticles, nanorods and nanosheets, formed of metal or metal alloy.

9. The method according to claim 8, wherein, the metal or metal alloy nanowire comprises one or more of nickel, cobalt, ferrosoferric oxide, and magnetic alloy nanowires.

10. The method according to claim 9, wherein, the magnetic alloy comprises at least two of nickel, cobalt, and ferrosoferric oxide.

11. The method according to claim 1, wherein, the transparent substrate used in the step S2 is made of polyethylene terephthalate (PET), polymethylmethacrylate (PMMA), polycarbonate (PC), polyethylene (PE), polystyrene (PS), polyimide (PI) or polyvinyl alcohol (PVA); and wherein, the transparent substrate has a thickness of 10 to 500 μm.

12. The method according to claim 1, wherein, the electrically conductive shielding layer in the step S2 has a thickness of 0.02 to 1 mm; and wherein, the magnetic field shielding layer in the step S2 has a thickness of 0.02 to 1 mm.

13. The method according to claim 1, wherein, the calcium chloride solution used in the step S3 has a CaCl₂ concentration of 1 to 10 wt. %.

14. An electromagnetic shielding film made by the method according to claim 1.

15. The method according to claim 2, wherein, the conductive agent is one or more of carbon nanotubes, graphene, silver nanowires, copper nanowires, polythiophene, and polypyrrole.

16. The method according to claim 15, wherein, the conductive agent has a one-dimensional nano-structure.

17. The method according to claim 16, wherein, the conductive agent is one or more of carbon nanotubes, silver nanowires, and copper nanowires.

18. The method according to claim 6, wherein, the magnetic nanomaterial used in the step S1 is one or more of nickel, cobalt, and ferrosoferric oxide.

19. An electromagnetic shielding film made by the method according to claim 2.

20. An electromagnetic shielding film made by the method according to claim 3.
